(19) United States
(12) Patent Application Publication
(10) Pub. No.: US 2005/0041566 A1
(43) Pub. Date: Feb. 24, 2005

(54) Apparatus and method for recording image information for creation of a three-dimensional image

(76) Inventors: Sultan Haider, Erlangen (DE); Bernard Hammer, Pfaffing (DE)

Correspondence Address: HARNESS, DICKEY & PIERCE, P.L.C., P.O.BOX 8910, RESTON, VA, 20195, US

(21) Appl. No.: 10/915,376

(22) Filed: Aug. 11, 2004

(30) Foreign Application Priority Data
Aug. 11, 2003 (DE) 10336736.5

(51) Int. Cl. G11B 7/00; H01L 27/00

(52) U.S. Cl. 369/125

(57) ABSTRACT

An apparatus is for recording image information for creation of a three-dimensional image. The apparatus includes a lens for creation of a real image of a three-dimensional object and a sensor for selective recording of image signals on the basis of the real image. The relative position of the sensor with respect to the lens can be moved. The apparatus further includes a control unit for controlling the position of the sensor as a function of the recorded image signals.

The present application hereby claims priority under 35 U.S.C. §119 on German patent application number DE 103 36 736.5 filed Aug. 11, 2003, the entire contents of which are hereby incorporated herein by reference.

### FIELD OF THE INVENTION

The present invention generally relates to an apparatus for recording image information for creation of a three-dimensional image, and generally relates to a method for recording image information for creation of a three-dimensional image.

### BACKGROUND OF THE INVENTION

A camera, for example, can be used to create two-dimensional recordings of a three-dimensional object. However, these images lack exact depth information which, for example, may be of major importance when making recordings in the medical field. There may therefore be a requirement for an appropriate apparatus and a method by which a three-dimensional image can be created from two-dimensional images.

In order to determine three-dimensional information from a single imaging sensor when using a monocular camera, the camera focus is adjusted continuously over a specific range over a predetermined recording time period. The distance to the image area can be deduced by subsequent analysis of the clarity of specific image areas in the image sequence, and comparison with the respective focus setting. In addition, sensors are used for infrared or ultrasound measurements. The success of this procedure is, however, dependent on an object which is as well structured as possible, ideally having a large number of edges, and on good illumination.

In the case of binocular systems, an object is recorded from two different viewing angles. Its three-dimensional position can thus be determined by searching for corresponding image points in both images. In the case of binocular systems, two cameras are used, by way of example, or the camera must be scanned, so that the object can be recorded from different viewing angles. For three-dimensional position determination such as this to be successful, a computation-intensive correspondence search of the two images is required in order to ensure that one pixel in each of the two images originates from the same point. If the object to be investigated does not have sufficient structure, a plausible match is impossible, and no sensible distance value can be determined. Furthermore, the use of two cameras, and scanning when using only one camera, are complex and tedious.

### SUMMARY OF THE INVENTION

An object of an embodiment of the present invention includes providing an apparatus and a method for recording image information for creation of a three-dimensional image. Preferably, it is less complex than the already known monocular and binocular systems, and/or realistic three-dimensional images even can be created in poor image conditions, for example with poor illumination or with little color depth.

According to an embodiment of the invention, an object may be achieved by an apparatus and/or by a method.

According to an embodiment of the present invention, an apparatus is described for recording image information for creation of a three-dimensional image, having a lens for creation of a real image of a three-dimensional object, a sensor for selective recording of image signals on the basis of the real image, in which case the relative position of the sensor with respect to the lens can be moved, and a control unit for controlling the position of the sensor as a function of the recorded image signals.

Furthermore, an embodiment of the present invention describes a method for recording image information for creation of a three-dimensional image, comprising the following steps: creation of a real image of a three-dimensional object by use of a lens, selective recording of image signals on the basis of the real image by means of a sensor, movement of the relative position of the sensor with respect to the lens, and control of the position of the sensor as a function of the recorded image signals by way of a control unit.

The use of a movable sensor makes it possible to create records of the three-dimensional object from different viewing angles, thus allowing three-dimensional reconstruction.

Furthermore, the control of the position of the sensor as a function of the already recorded image signals allows optimum matching to the given recording conditions, thus allowing high image quality to be achieved in the creation of the three-dimensional image.

According to one preferred exemplary embodiment of the invention, the sensor can be moved along three mutually perpendicular axes.

The plane of the sensor can preferably be tilted relative to the position of the optical axis.

The sensor is advantageously suitable for recording image signals in the form of luminance values.

Furthermore, the sensor is advantageously suitable for recording image signals in the form of chrominance signals.

The control unit can check the image signals recorded by the sensor on the basis of predetermined parameters.

The sensor preferably records image signals in order to determine the edges of the three-dimensional object.

Furthermore, the sensor advantageously records image signals in order to determine the depth of the edges of the three-dimensional object.

The control unit can transmit the recorded image signals to an RF transmitter with an antenna.

### BRIEF DESCRIPTION OF THE DRAWINGS

Further advantages, features and details of the invention will become evident from the description of illustrated exemplary embodiments given hereinbelow and the accompanying drawings, which are given by way of illustration only and thus are not limitative of the present invention, wherein:

FIG. 1 shows a schematic block diagram of the apparatus according to an embodiment of the invention,

FIG. 2 shows a flowchart for the process of edge determination, and

FIG. 3 shows a flowchart for the process of depth determination.

### DETAILED DESCRIPTION OF THE PREFERRED EMBODIMENTS OF THE INVENTION

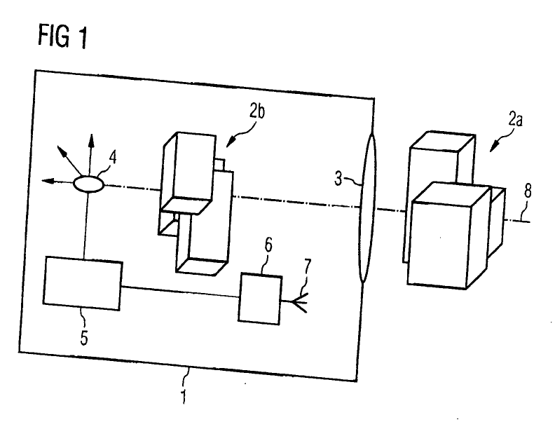

FIG. 1 shows a schematic block diagram of one preferred exemplary embodiment of the apparatus according to the invention, with a camera 1 for recording images in the vicinity. In this case, this may relate to people, objects, areas, outdoor areas or, for medical purposes, body internal areas, in which one or more three-dimensional objects 2a is or are located.

A real image 2b of the three-dimensional object 2a is created by use of a lens 3. In the simplest case, the lens 3 may be a concave imaging lens, or a lens system including two or more lenses. A sensor 4 is used to record image signals of the three-dimensional object 2a on the basis of the real image 2b, which is projected into the camera 1 through the lens 3. The sensor 4 is in this case smaller than the real image 2b within the camera 1, and can be moved in the direction of three mutually perpendicular axes.

Furthermore, the plane of the sensor 4 can also be changed with respect to the position of the optical axis 8. In this case, the sensor 4 is suitable to record image signals in the form of luminance or chrominance values. The movement of the sensor 4 allows the three-dimensional object 2a to be recorded from different viewing angles and in different conditions, as a result of which edges and shadows can be made detectable, thus making it possible to create a three-dimensional image with depth information.

The sensor 4 transmits the recorded image signals to a control unit 5, which checks the received image signals on the basis of predetermined parameters, and changes the position of the sensor 4 on the basis of the results obtained from this check. The control unit 5 transmits the image signals, which have been transmitted from the sensor 4, to an RF transmitter 6 with an antenna 7 for transmission of the image signals to an external image processing unit (not illustrated) for construction of a three-dimensional image on the basis of the transmitted image signals.

Alternatively, instead of the RF transmitter 6 and the antenna 7, the image processing unit can be implemented directly in the camera 1, with a screen which is likewise integrated in the camera and on which the complete three-dimensional image is displayed. The sensor 4 can be controlled by the control unit 5 via an electromechanical, piezoelectric or mechanical system.

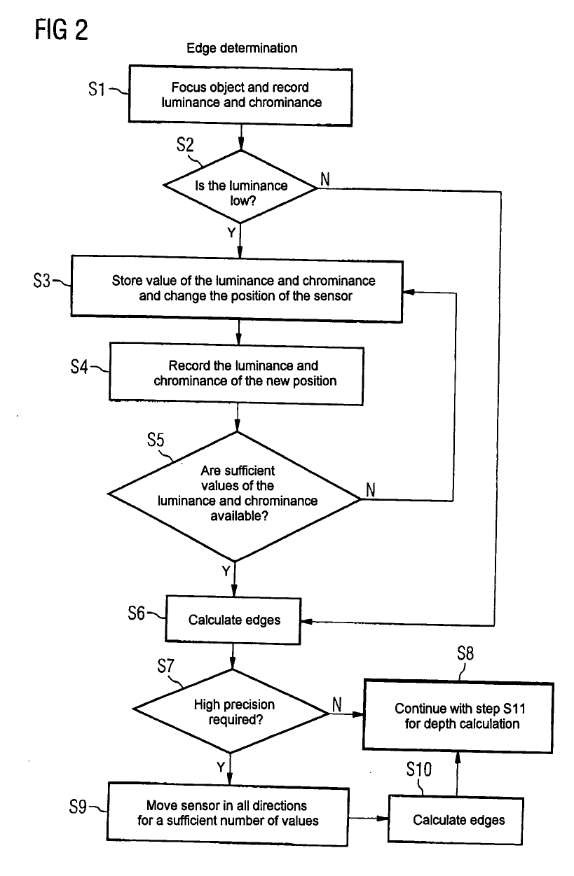

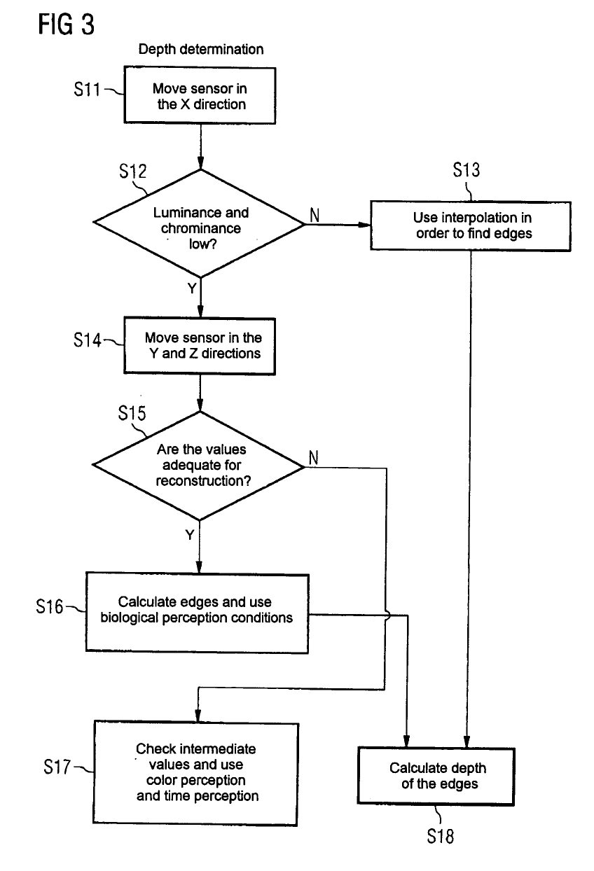

The details of the process for edge and depth determination as well as the reconstruction of a three-dimensional image from the individual selective image signals obtained by use of the sensor 4 are illustrated in FIGS. 2 and 3. The procedure in this case includes both the recording of luminance and chrominance by the sensor 4, the checking of the recorded image signals on the basis of predetermined parameters by the control unit 5, and the evaluation and calculation by the image processing unit, which is not illustrated, in order to create the three-dimensional image.

In this case, the tasks of parameter checking, control of the sensor and final calculations and image constructions may be distributed differently, depending on the desired use of the camera 1. In the case of a particularly small camera 1, as is used by way of example for medical purposes, the control unit 5 will only check the image signals on the basis of specific parameters, and will send the image signals via the RF transmitter 6 and the antenna 7 to an external image processing unit. However, if the aim is to view the images immediately, then the image processing unit may be implemented in the camera, or may coincide with the control unit, so that the images are post-processed directly in the camera.

The process procedure illustrated in FIGS. 2 and 3 is based on the mechanism of human visual perception, with depth, movement, color and brightness being recorded in order to create an image with a depth effect, and in which the recorded edges, surfaces, objects and color and/or brightness graduations are compiled in accordance with specific rules in order to form a three-dimensional image.

In the case of objects which do not move, the edge determination is first of all carried out in accordance with the flowchart as illustrated in FIG. 2. The object is focused in a step S1, and the sensor 4 records the luminance and the chrominance. The recorded image signals are transmitted to the control unit 5 which, in a step S2, checks whether the luminance is low. The criterion for this is whether it would be possible for the human eye to identify and resolve the object in the present scene.

If the luminance is not low, the edges can be calculated immediately, in a step S6, since they are clearly evident. However, if the luminance is too low in order to calculate the edges from one or a small number of selective records, the value of the luminance and of the chrominance at the position just recorded is stored, and the control unit 5 changes the position of the sensor 4.

In a next step S4, the sensor 4 records the luminance and chrominance once again at the new position. In the next step S5, the control unit 5 checks whether sufficient luminance and chrominance values are available in order to make it possible to determine the edges, that is to say whether reconstruction is possible on the basis of the already recorded values. If this is not the case, the process procedure returns to step S3 once again, and passes through steps S3 to S5.

If the control unit 5 decides in the step S5 that sufficient values are available for the luminance and chrominance, the edges are calculated in the next step S6. In a post-processing step S7, the control unit 5 checks whether particularly high precision is required for a specific object or a specific scenario. For example, greater precision must be achieved in the medical field, and better resolution must be achieved than when using the camera in a mobile telephone for snapshots or the like. If this is the case, the sensor 4 is moved by the control unit 5 to further positions until sufficient values are available for very precise construction.

The edges are then calculated in a step S10. If high precision is not required, or after recording further values for high precision, the process procedure in this step S8 is continued with a step S11 for depth determination.

FIG. 3 shows the process procedure for depth determination. In the step S11, the sensor is moved along the X direction, which corresponds to the optical axis 8, and the luminance and chrominance are recorded at different positions. In the step S12, the control unit 5 checks whether the luminance and chrominance for the recorded image signals are low.

Once again, the criterion for this is likewise whether it would be possible for the human eye to identify and to resolve the objects in the present scene. If this is not the case, the edges are determined by way of interpolation in a step S13, and the depth of the edges is calculated in a final step S18. If the control unit 5 decides in the step S12 that the luminance and prominence are low, the sensor is also moved in the Y and Z directions, which correspond to the two directions that are perpendicular to the X axis.

After recording different values in the Y and Z directions, the control unit 5 checks, in the step S15, whether the values are sufficient for reconstruction. If this is not the case, even more values are recorded by the sensor 4 at different positions and, finally, the depths of the edges are calculated by use of color analysis in a step S18. If the values are sufficient for reconstruction in step S15, the edges are calculated in the step S16, and biological perception conditions are applied. These are rules on the basis of which the human brain compiles the perceived edges and surfaces to form three-dimensional objects.

The process procedures described in FIG. 2 and FIG. 3 may be used in this form for objects and scenes which do not move. In the case of moving objects, the object is recorded from one position two or more times in step S1 in FIG. 2, or is recorded over a specific time period of several milliseconds ms, and the external image processing unit determines the frequency in the image change in addition to the luminance and chrominance as recorded by the sensor 4. The frequency change is likewise determined in the steps S4 in FIG. 2, S11 in FIG. 3 and S14 and S17 in FIG. 3. The movement of a specific object is in each case reconstructed from the individual recorded images by checking matches of edges, surfaces or shapes. The relative movements of the various objects with respect to one another and relative to the background are calculated, and the depth of the edges is then determined.

The apparatus according to an embodiment of the invention and the method according to an embodiment of the invention may be used in widely different fields. For example, the apparatus may be integrated in a digital camera which either allows subsequent post-processing in an external processing unit, for example a personal computer, with the digital camera sending the received image signals to this external processing unit, or the image processing may be integrated in the camera itself. A further option is to implement the apparatus in a mobile telephone for wire-free communication.

For the medical field, the apparatus according to an embodiment of the invention and the method according to an embodiment of the invention may be implemented in an endoscope. Endoscopes are used to examine the gastrointestinal tract and may be in the form of capsules which can be swallowed.

In the case of endoscopes in the form of capsules, the image signals recorded by the sensor 4 are transmitted by way of the control unit 5, the RF transmitter 6 and the antenna 7 to an external image processing unit, since processing must be carried out in a space-saving manner in the case of an endoscope which can be swallowed. Particularly in the case of the capsules which can be swallowed, the apparatus and method according to an embodiment of the invention offer the advantage over binocular systems that they operate with only one camera and avoid the necessity to scan, as in the case of monocular cameras.

Any of the aforementioned methods may be embodied in the form of a program. The program may be stored on a computer readable media and is adapted to perform any one of the aforementioned methods when run on a computer. Thus, the storage medium or computer readable medium, is adapted to store information and is adapted to interact with a data processing facility or computer to perform the method of any of the above mentioned embodiments.

The storage medium may be a built-in medium installed inside a computer main body or removable medium arranged so that it can be separated from the computer main body. Examples of the built-in medium include, but are not limited to, rewriteable involatile memories, such as ROMs and flash memories, and hard disks. Examples of the removable medium include, but are not limited to, optical storage media such as CD-ROMs and DVDs; magneto-optical storage media, such as MOs; magnetism storage media, such as floppy disks (trademark), cassette tapes, and removable hard disks; media with a built-in rewriteable involatile memory, such as memory cards; and media with a built-in ROM, such as ROM cassettes.

Exemplary embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

1. An apparatus for recording image information for creation of a three-dimensional image, comprising:
a lens for creation of a real image of a three-dimensional object;
a sensor for selective recording of image signals on the basis of the real image, wherein a relative position of the sensor with respect to the lens is movable; and
a control unit for controlling the position of the sensor as a function of the recorded image signals.

2. The apparatus as claimed in claim 1, wherein the sensor is movable along three mutually perpendicular axes.

3. The apparatus as claimed in claim 1, wherein a plane of the sensor is tiltable relative to the position of an optical axis of the lens.

4. The apparatus as claimed in claim 1, wherein the sensor is suitable for recording image signals in the form of luminance values.

5. The apparatus as claimed in claim 1, wherein the sensor is suitable for recording image signals in the form of chrominance values.

6. The apparatus as claimed in claim 1, wherein the control unit checks the image signals recorded by the sensor on the basis of predetermined parameters.

7. The apparatus as claimed in claim 1, wherein the sensor records image signals in order to determine the edges of the three-dimensional object.

8. The apparatus as claimed in claim 1, wherein the sensor records image signals in order to determine the depth of edges of the three-dimensional object.

9. The apparatus as claimed in claim 1, wherein the control unit transmits the recorded image signals to an RF transmitter with an antenna.

10. A method for recording image information for creation of a three-dimensional image, comprising:
creating a real image of a three-dimensional object using a lens;
selectively recording image signals on the basis of the real image using a sensor, wherein a relative position of the sensor is movable with respect to the lens; and
controlling the position of the sensor as a function of the recorded image signals.

11. The method as claimed in claim 10, wherein the sensor is movable along three mutually perpendicular axes.

12. The method as claimed in claim 10, further comprising :
tilting of the plane of the sensor relative to the position of an optical axis of the lens.

13. The method as claimed in claim 10, wherein the image signals are selectively recorded in the form of luminance values.

14. The method as claimed in claim 10, wherein the image signals are selectively recorded in the form of chrominance values.

15. The method as claimed in claim 10, further comprising:
checking the image signals recorded by the sensor on the basis of predetermined parameters.

16. The method as claimed in claim 10, wherein the image signals are recorded by the sensor in order to determine the edges of the three-dimensional object.

17. The method as claimed in claim 10, wherein the image signals are recorded by the sensor in order to determine the depth of edges of the three-dimensional object.

18. The method as claimed in claim 10, further comprising:
transmitting the recorded image signals to an RF transmitter via an antenna.

19. The apparatus as claimed in claim 2, wherein a plane of the sensor is tiltable relative to the position of an optical axis of the lens.

20. The method as claimed in claim 11, further comprising :
tilting of the plane of the sensor relative to the position of an optical axis of the lens.

21. The method as claimed in claim 16, wherein the image signals are recorded by the sensor in order to determine the depth of the edges of the three-dimensional object.

22. The apparatus as claimed in claim 7, wherein the sensor records image signals in order to determine the depth of edges of the three-dimensional object.

23. An apparatus for recording image information for creation of a three-dimensional image, comprising:
means for creating a real image of a three-dimensional object;
means for selectively recording image signals on the basis of the real image, wherein a relative position of the means for selectively recording image signals is movable with respect to the means for creating a real image; and
means for controlling the position of the means for selectively recording image signals as a function of the recorded image signals.

24. The apparatus as claimed in claim 23, wherein the means for selectively recording image signals is movable along three mutually perpendicular axes.

25. The apparatus as claimed in claim 23, further comprising :
means for tilting of the plane of the means for selectively recording image signals relative to the position of an optical axis of the means for creating a real image.

26. The apparatus as claimed in claim 23, wherein the image signals are selectively recorded in the form of luminance values.

27. The apparatus as claimed in claim 23, wherein the image signals are selectively recorded in the form of chrominance values.

28. The apparatus as claimed in claim 23, further comprising:
means for checking the image signals recorded by the means for selectively recording image signals on the basis of predetermined parameters.

29. The apparatus as claimed in claim 23, wherein the image signals are recorded by the means for selectively recording image signals in order to determine the edges of the three-dimensional object.

30. The apparatus as claimed in claim 23, wherein the image signals are recorded by the means for selectively recording image signals in order to determine the depth of edges of the three-dimensional object.

31. The apparatus as claimed in claim 23, further comprising:
means for transmitting the recorded image signals to an RF transmitter.

32. A digital camera, including the apparatus of claim 1.

33. A digital camera, including the apparatus of claim 23.

34. A mobile telephone, including the apparatus of claim 1.

35. A mobile telephone, including the apparatus of claim 23.

36. An endoscope, including the apparatus of claim 1.

37. An endoscope, including the apparatus of claim 23.

38. A digital camera for performing the method of claim 10.

39. A mobile phone for performing the method of claim 10.

40. An endoscope for performing the method of claim 10.

41. A program, adapted to perform the method of claim 10, when executed on a computer.

42. A computer readable medium, storing the program of claim 41.
